(19) United States
(12) Patent Application Publication
(10) Pub. No.: US 2008/0157862 A1
(43) Pub. Date: Jul. 3, 2008

(54) NOISE CANCELLATION CIRCUIT, ELECTRONIC CIRCUIT, AND NOISE CANCELLATION SIGNAL GENERATION METHOD

(75) Inventors: Koichi HATANAKA, Matsumoto (JP); Kazumi MATSUMOTO, Shiojiri (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 11/959,105

(22) Filed: Dec. 18, 2007

(30) Foreign Application Priority Data
Dec. 28, 2006 (JP) 2006-354834

(51) Int. Cl. H03K 5/00

(52) U.S. Cl. 327/551

(57) ABSTRACT

A coil section detects undesirable radiation generated from a baseband process circuit section mounted at a specific position on a substrate, the coil section including a wire with a specific shape that is disposed at a position close to the baseband process circuit section, and a cancellation signal generation section generates a signal that cancels the undesirable radiation detected by the coil section.

Japanese Patent Application No. 2006-354834 filed on Dec. 28, 2006, is hereby incorporated by reference in its entirety.

### BACKGROUND OF THE INVENTION

The present invention relates to a noise cancellation circuit, an electronic circuit, and a noise cancellation signal generation method.

A phenomenon called crosstalk is known in which a signal transmitted through one channel is superimposed on another channel. Since crosstalk causes a significant deterioration in signal quality, various technologies have been proposed to prevent crosstalk or remove a mixed crosstalk component.

For example, U.S. Pat. No. 7,050,388 discloses technology which removes a mixed crosstalk component by generating a signal which cancels the mixed crosstalk component (hereinafter referred to as “cancellation signal”).

In a module in which a digital signal processing circuit section and an analog signal processing circuit section are mounted on a substrate, the characteristics of the analog signal processing circuit section may deteriorate due to high-frequency noise (hereinafter referred to as “undesirable radiation”) generated by the digital signal processing circuit section. In this case, a cancellation signal which cancels undesirable radiation generated from the digital signal processing circuit section may be generated by applying the technology disclosed in U.S. Pat. No. 7,050,388, and added to a signal in the processing system of the analog signal processing circuit section. However, it is difficult to efficiently detect undesirable radiation.

The effects of undesirable radiation generated from the digital signal processing circuit section may be reduced by mounting the analog signal processing circuit section at a position sufficiently away from the digital signal processing circuit section. In this case, the size of the entire module inevitably increases.

### SUMMARY

According to one aspect of the invention, there is provided a noise cancellation circuit comprising:

a coil section that includes a wire with a specific shape that is disposed at a position close to a digital signal processing circuit section mounted at a specific position on a substrate, the coil section detecting undesirable radiation generated from the digital signal processing circuit section; and

a cancellation signal generation section that generates a signal that cancels the undesirable radiation detected by the coil section.

According to another aspect of the invention, there is provided a noise cancellation signal generation method comprising:

disposing a coil section that detects undesirable radiation generated from a digital signal processing circuit section mounted at a specific position on a substrate, the coil section including a wire with a specific shape that is disposed at a position close to the digital signal processing circuit section; and

generating a signal that cancels the undesirable radiation detected by the coil section.

### BRIEF DESCRIPTION OF THE SEVERAL VIEWS OF THE DRAWING

FIG. 1 is a block diagram showing the configuration of a GPS module.

FIG. 2 is a view illustrative of the form of a coil section.

FIG. 3 is a vertical cross-sectional view showing a portion around a RAM.

FIG. 4 is a vertical cross-sectional view showing a portion around a RAM according to a modification.

FIG. 5 is a view illustrative of the form of a coil section according to a modification.

FIG. 6 is a view illustrative of the form of a coil section according to another modification.

FIG. 7 is a view illustrative of the form of a coil section according to a further modification.

### DETAILED DESCRIPTION OF THE EMBODIMENT

According to one embodiment of the invention, there is provided a noise cancellation circuit comprising:

a coil section that includes a wire with a specific shape that is disposed at a position close to a digital signal processing circuit section mounted at a specific position on a substrate, the coil section detecting undesirable radiation generated from the digital signal processing circuit section; and

a cancellation signal generation section that generates a signal that cancels the undesirable radiation detected by the coil section.

According to another embodiment of the invention, there is provided a noise cancellation signal generation method comprising:

disposing a coil section that detects undesirable radiation generated from a digital signal processing circuit section mounted at a specific position on a substrate, the coil section including a wire with a specific shape that is disposed at a position close to the digital signal processing circuit section; and

generating a signal that cancels the undesirable radiation detected by the coil section.

According to the above configuration, the coil section that includes a wire with a specific shape disposed at a position close to the digital signal processing circuit section detects undesirable radiation generated from the digital signal processing circuit section mounted at a specific position on the substrate, and the cancellation signal generation section generates the signal that cancels the detected undesirable radiation.

For example, undesirable radiation generated from the digital signal processing circuit section can be efficiently detected by forming the coil section on the substrate directly under the digital signal processing circuit section. According to this configuration, since other electronic circuits such as an analog signal processing circuit section can be mounted near the digital signal processing circuit section, an increase in the entire module size can be prevented, and the degree of freedom relating to the circuit layout design can be increased.

In the noise cancellation circuit, the coil section may be disposed between the digital signal processing circuit section and the substrate.

The noise cancellation signal generation method may further include: disposing the coil section between the digital signal processing circuit section and the substrate.

According to the above configuration, undesirable radiation generated from the digital signal processing circuit section is detected by the coil section disposed between the digital signal processing circuit section and the substrate.

In the noise cancellation circuit, the coil section may be disposed between a specific circuit section and the substrate, the specific circuit section forming the digital signal processing circuit section.

The noise cancellation signal generation method may further include: disposing the coil section between a specific circuit section and the substrate, the specific circuit section forming the digital signal processing circuit section.

According to the above configuration, undesirable radiation generated from the specific circuit section of the digital signal processing circuit section is detected by the coil section disposed between the specific circuit section and the substrate.

In the noise cancellation circuit, the coil section may be disposed between a memory circuit section and the substrate, the memory circuit section forming the digital signal processing circuit section.

The noise cancellation signal generation method may further include: disposing the coil section between a memory circuit section and the substrate, the memory circuit section forming the digital signal processing circuit section.

According to the above configuration, undesirable radiation generated from the memory circuit section of the digital signal processing circuit section is detected by the coil section disposed between the memory circuit section and the substrate.

In the noise cancellation circuit, the coil section may include a wire disposed along a periphery of the digital signal processing circuit section.

The noise cancellation signal generation method may further include: forming the coil section using a wire disposed along a periphery of the digital signal processing circuit section.

According to the above configuration, undesirable radiation generated from the digital signal processing circuit section is detected by the coil section formed of a wire disposed along the periphery of the digital signal processing circuit section.

According to a further embodiment of the invention, there is provided an electronic circuit comprising one of the above noise cancellation circuits and the digital signal processing circuit section.

In the electronic circuit, the digital signal processing circuit section may be flip-chip mounted over the coil section.

According to the above configuration, since the coil section faces the circuit surface of the digital signal processing circuit section, undesirable radiation generated from the digital signal processing circuit section can be efficiently detected.

In the electronic circuit, the digital signal processing circuit section may be a GPS satellite signal processing circuit section.

According to the above configuration, a signal that cancels undesirable radiation generated from the GPS satellite signal processing circuit section is generated.

Embodiments of the invention are described below with reference to the drawings. Note that the embodiments described below do not in any way limit the scope of the invention laid out in the claims. Note that all elements of the embodiments described below should not necessarily be taken as essential requirements for the invention.

An embodiment in which the invention is applied to a global positioning system (GPS) module is described below with reference to the drawings.

### 1. Configuration

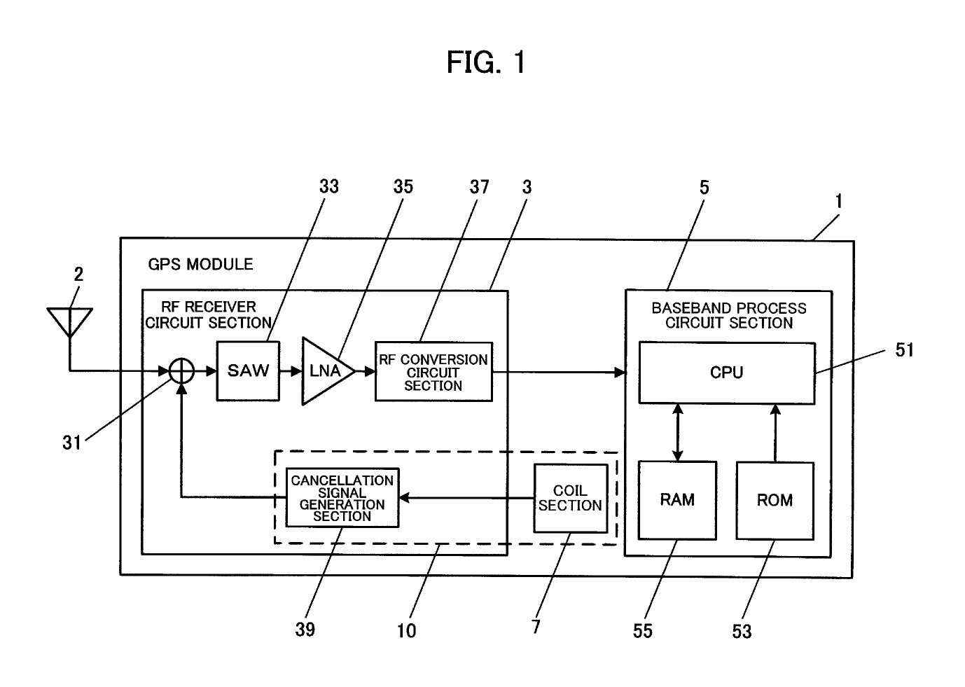

FIG. 1 is a block diagram showing the functional configuration of a GPS module 1 according to this embodiment. The GPS module 1 includes a radio frequency (RF) receiver circuit section 3, a baseband process circuit section 5, and a coil section 7.

The coil section 7 and a cancellation signal generation section 39 included in the RF receiver circuit section 3 form a noise cancellation circuit 10 which is a characteristic configuration according to this embodiment. The RF receiver circuit section 3 and the baseband process circuit section 5 may be produced as different large scale integrated (LSI) circuits, or may be produced in one chip.

The RF receiver circuit section 3 is an RF signal receiver circuit which includes an addition section 31, a surface acoustic wave (SAW) filter 33, a low-noise amplifier (LNA) 35, an RF conversion circuit section 37, and the cancellation signal generation section 39.

The addition section 31 is an adder which adds a cancellation signal generated by the cancellation signal generation section 39 to an RF signal including a GPS satellite signal as a radio signal received by a GPS antenna 2. The addition section 31 outputs an addition result signal to the SAW filter 33.

The SAW filter 33 is a bandpass filter which allows a specific frequency band component of the signal output from the addition section 31 to pass through, and outputs the signal which has passed through the SAW filter 33 to the LNA 35.

The LNA 35 is a low-noise amplifier which amplifies the signal which has passed through the SAW filter 33, and outputs the amplified signal to the RF conversion circuit section 37.

The RF conversion circuit section 37 down-converts the RF signal into an intermediate-frequency signal (hereinafter referred to as “IF (intermediate frequency) signal”) by multiplying the signal amplified by the LNA 35 by a specific oscillation signal. The RF conversion circuit section 37 then subjects the IF signal to amplification and the like, converts the IF signal into a digital signal using an A/D converter, and outputs the resulting digital signal to the baseband process circuit section 5.

The cancellation signal generation section 39 is a circuit section which generates a signal (hereinafter referred to as “cancellation signal”) which cancels undesirable radiation generated from the baseband process circuit section 5 and detected by the coil section 7. The cancellation signal generation section 39 outputs the generated cancellation signal to the addition section 31. The cancellation signal generation section 39 includes a phase shifter section which shifts the phase of the undesirable radiation input from the coil section 7 by 180 degrees, and an attenuation section which attenuates the signal phase-shifted by the phase shifter section by a specific attenuation factor, for example.

In the GPS module 1, since the RF receiver circuit section 3 and the baseband process circuit section 5 are disposed at nearby positions, undesirable radiation generated from the baseband process circuit section 5 is superimposed as noise on the signal output from the GPS antenna 2 to the RF receiver circuit section 3. However, since the cancellation signal generated by the cancellation signal generation section 39 is added to the signal output from the GPS antenna 2 by the addition section 31, the noise superimposed due to the undesirable radiation is canceled.

The baseband process circuit section 5 is a circuit section which acquires/extracts the GPS satellite signal by performing a correlation process and the like on the IF signal output from the RF conversion circuit section 3, decodes data contained in the GPS satellite signal to extract a navigation message, time information, and the like, and performs pseudo-range calculations, positioning calculations, and the like. The GPS satellite signal is a spread spectrum modulated signal called a coarse and acquisition (C/A) code.

The baseband process circuit section 5 includes a circuit which performs the correlation process, a circuit which generates a spread code (code replica) for performing correlation calculations, a circuit which decodes data, a central processing unit (CPU) 51 which is a processor that controls each section of the baseband process circuit section 5 and the RF reception circuit section 3 and performs various calculations, a read only memory (ROM) 53, and a random access memory (RAM) 55 (memory circuit section).

The coil section 7 includes a wire with a specific shape formed at a position close to the baseband process circuit section 5. The coil section 7 detects undesirable radiation generated from the baseband process circuit section 5, and outputs the detected undesirable radiation to the cancellation signal generation section 39.

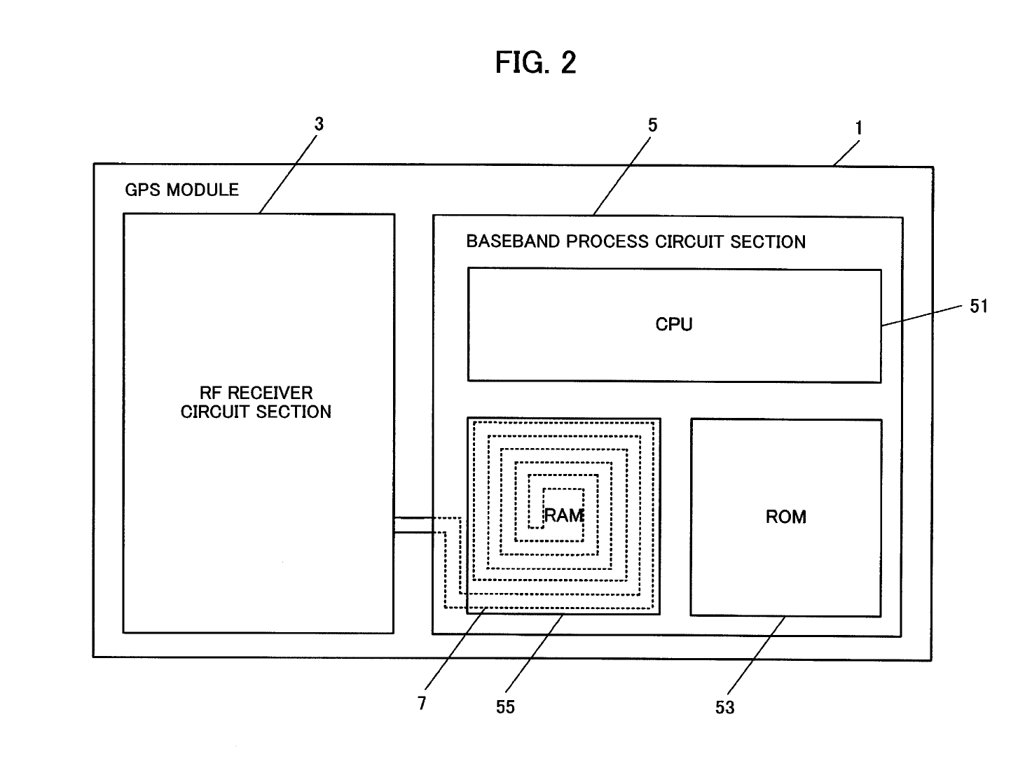

FIG. 2 is a view illustrative of the form of the coil section 7.

Each circuit section of the baseband process circuit section 5 generates undesirable radiation accompanying its circuit operation. In particular, the RAM 55 is a circuit section which generates undesirable radiation at a high signal level. In this embodiment, undesirable radiation mainly generated from the RAM 55 is detected by forming the coil section 7 on a substrate under the RAM 55.

The coil section 7 is formed of a spiral coil wire called a spiral inductor. The size of the coil section 7 is almost the same as that of the RAM 55. The line width and the line-to-line distance of the spiral inductor are a matter of design. In order to effectively detect undesirable radiation, it is desirable that the number of windings be three or more.

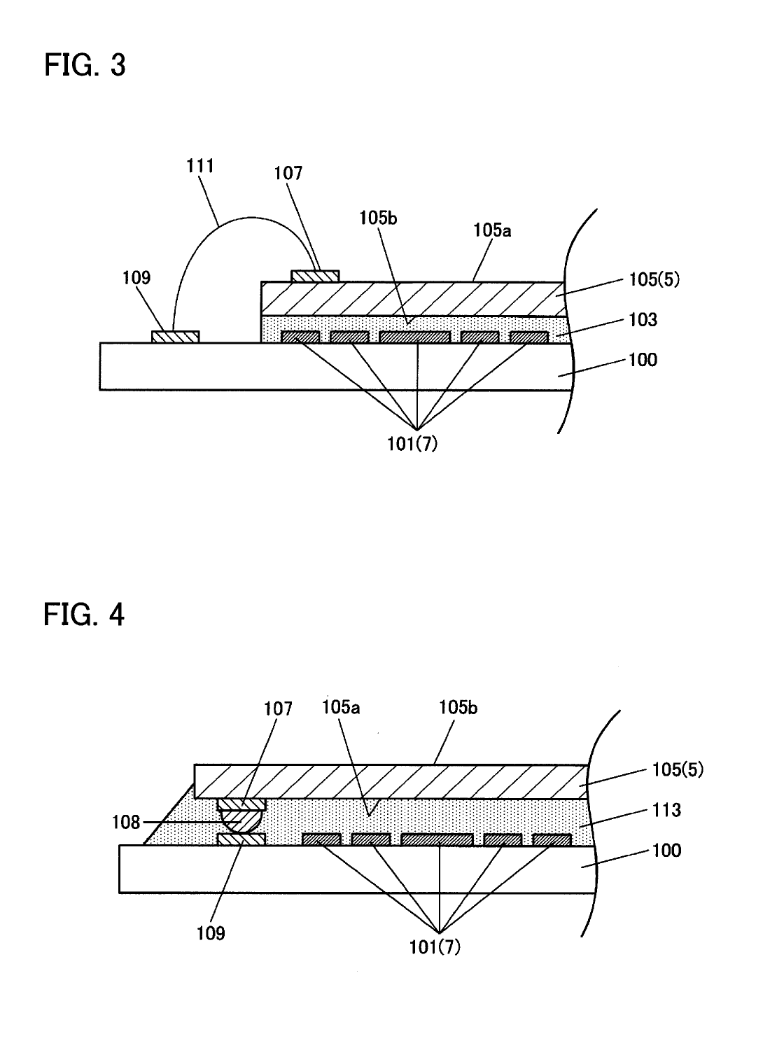

FIG. 3 is a vertical cross-sectional view showing a portion of the baseband process circuit section 5 around the RAM 55. Note that a substrate 100 is not hatched since a plurality of layers such as an interconnect layer are formed in the substrate 100.

A spiral inductor 101 (coil section 7) is formed on the top surface of the substrate 100 using a substrate wire. A chip 105 of the baseband process circuit section 5 (hereinafter referred to as “baseband integrated circuit (BBIC)”) is bonded/mounted on the substrate 100 through an adhesive layer 103 in a state in which a circuit surface 105a faces the upper side.

A terminal electrode 107 is formed on the circuit surface 105a of the BBIC 105. The terminal electrode 107 is connected to a substrate electrode 109 formed on the substrate 100 via a bonding wire 111 formed of a metal such as Al, Cu, or Au. The BBIC 105 is mounted using a face-up mounting method known as wire-bond mounting.

As the material for the adhesive layer 103 which bonds the substrate 100 and the BBIC 105, an adhesive such as an epoxy resin may be used. Since the spiral inductor 101 cannot detect undesirable radiation generated from the BBIC 105 when the adhesive layer 103 has a low permeability, it is desirable to increase the permeability of the adhesive layer 103 by diffusion of a magnetic powder such as ferrite, for example.

### 2. Effects

According to this embodiment, undesirable radiation generated from the baseband process circuit section 5 mounted at a specific position of the substrate 100 is detected by the coil section 7 which includes the wire with a specific shape formed at a position close to the baseband process circuit section 5, and a signal which cancels the undesirable radiation detected by the coil section 7 is generated by the cancellation signal generation section 39.

Since the coil section 7 is formed under the RAM 55 which is the memory circuit section forming the baseband process circuit section 5, undesirable radiation at a high signal level mainly generated from the RAM 55 can be efficiently detected. Since noise due to undesirable radiation superimposed on the signal received by the GPS antenna 2 is canceled by the noise cancellation signal generated by the cancellation signal generation section 39, the RF receiver circuit section 3 and the baseband process circuit section 5 can be mounted at nearby positions without restrictions on the distance between the RF receiver circuit section 3 and the baseband process circuit section 5, thereby contributing to a reduction in module size and an increase in degree of freedom relating to the circuit layout design.

### 3. Other Embodiments

3-1. Digital Signal Processing Circuit Section

The invention may be applied to an arbitrary circuit section which performs digital signal processing in addition to the baseband process circuit section 5. Specifically, the invention may be applied to a digital signal processing circuit section which generates undesirable radiation accompanying its circuit operation.

3-2. Mounting Method

The above embodiment illustrates an example in which the BBIC 105 is mounted using wire-bond mounting. Note that the mounting method is not limited thereto.

FIG. 4 is a vertical cross-sectional view showing a portion around the RAM 55 when mounting the BBIC 105 using flip-chip mounting. The term “flip-chip mounting” refers to a face-down mounting method in which a chip is mounted in a state in which the circuit surface of the chip faces a substrate.

The spiral inductor 101 is formed on the substrate 100 using a substrate wire in the same manner as in FIG. 3. A protruding electrode called a bump 108 is formed of a metal such as Au or Pb on the terminal electrode 107 of the BBIC 105. The BBIC 105 is mounted on the substrate 100 in a state in which the circuit surface 105a faces the lower side so that the bump 108 contacts the substrate electrode 109.

A resin adhesive called an underfill 113 is provided and cured in the space between the substrate 100 and the BBIC 105. In this case, it is also desirable to increase the permeability of the underfill 113 by providing a magnetic powder or the like in order to enable the spiral inductor 101 to detect undesirable radiation.

Since the spiral inductor 101 faces the circuit surface 105a of the BBIC 105 when applying flip-chip mounting, undesirable radiation generated from the BBIC 105 can be efficiently detected as compared with the case of applying wire-bond mounting.

3-3. Shape of Coil Section

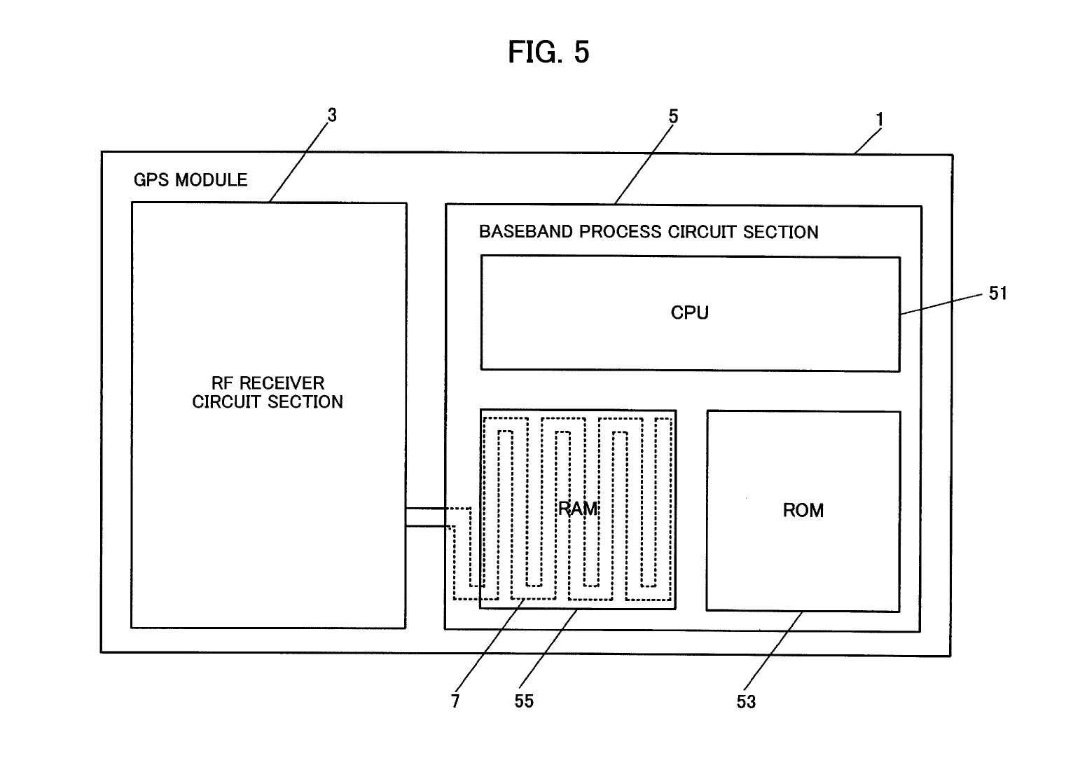

The above embodiment illustrates an example in which the coil section 7 has a spiral shape. Note that the coil section 7 may have other shapes. As shown in FIG. 5, a zigzag coil wire called a meander inductor may be formed on the substrate under the RAM 55. The line width and the line-to-line distance of the meander inductor are a matter of design. In order to effectively detect undesirable radiation, it is desirable that the number of parallel lines (paths) be three or more.

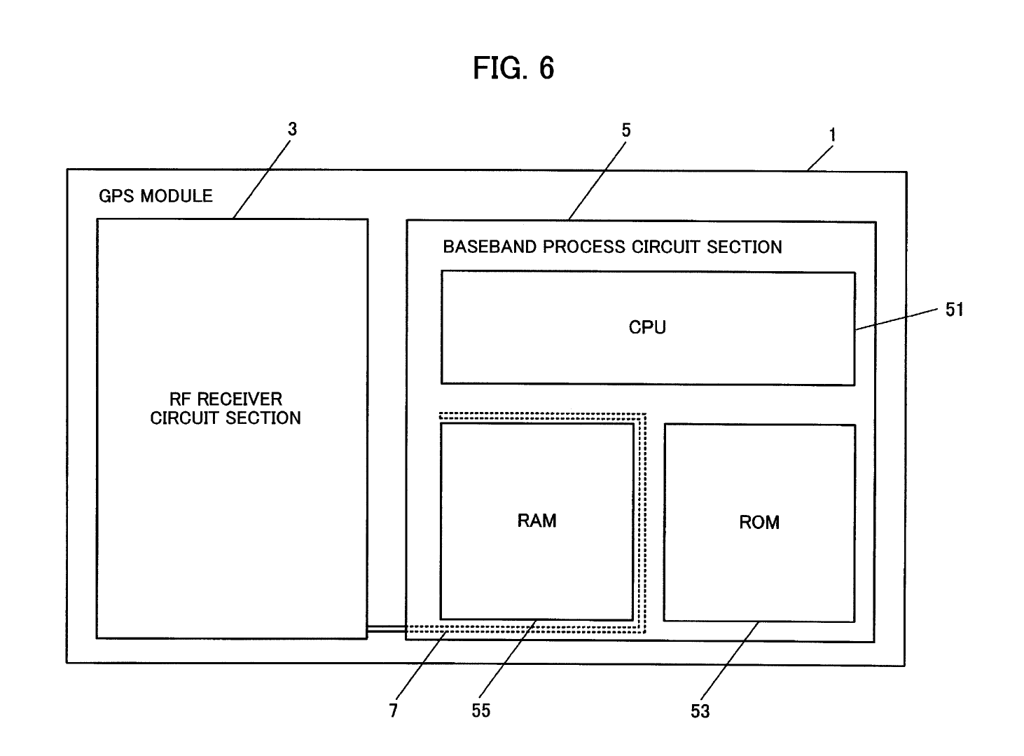

A coil wire may be formed along the periphery of the baseband process circuit section 5. In FIG. 6, a coil wire in the shape of a reversed letter “C” is formed along the periphery of the RAM 55, for example. Undesirable radiation can also be detected by merely providing a wire around the undesirable radiation source in this manner.

3-4. Position and Size of Coil Section

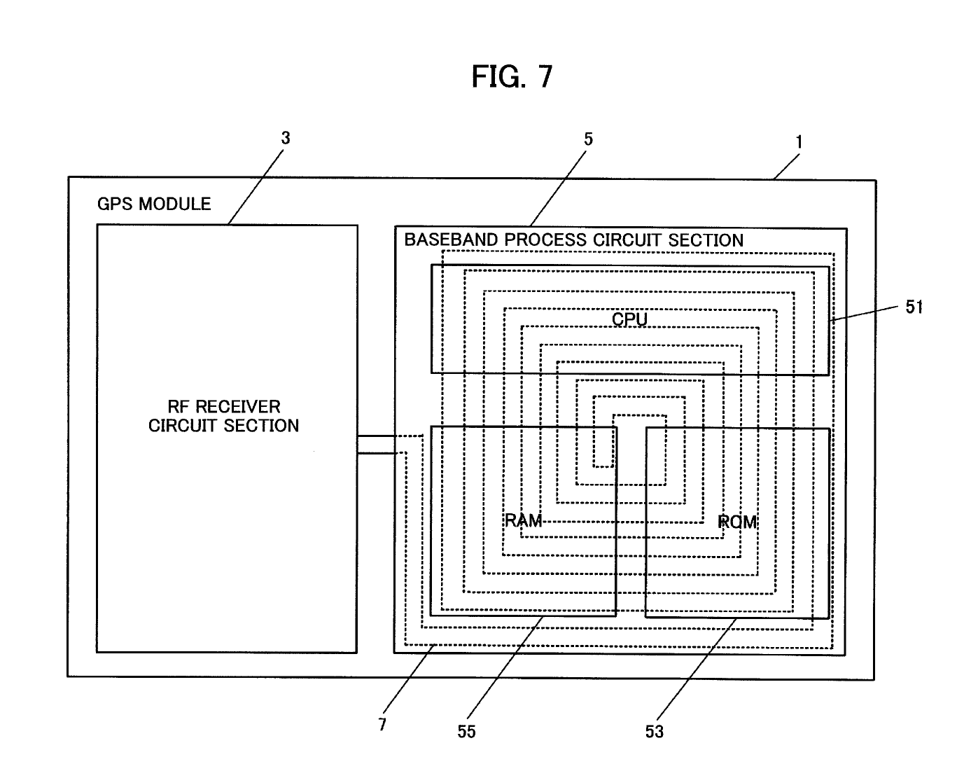

The coil section 7 may be formed under the CPU 51 or the ROM 53 instead of forming the coil section 7 under the RAM 55. Or, coil sections may be respectively formed under the RAM 55, the CPU 51, and the ROM 53 and connected in parallel. As shown in FIG. 7, the coil section 7 may be formed to cover the entire baseband process circuit section. In this case, undesirable radiation generated from the CPU 51 and the ROM 53 can be efficiently detected in addition to undesirable radiation generated from the RAM 55.

The coil section 7 may be stacked/formed in the substrate 100 instead of stacking the coil section 7 on the substrate 100.

3-5. Noise Cancellation Circuit

The above embodiment illustrates an example in which the cancellation signal generation section 39 of the noise cancellation circuit 10 is provided in the RF receiver circuit section 3. Note that the cancellation signal generation section 39 may be formed as a circuit section separated from the RF receiver circuit section 3 so that the noise cancellation circuit 10 may be provided independently.

Although only some embodiments of the invention have been described above in detail, those skilled in the art would readily appreciate that many modifications are possible in the embodiments without materially departing from the novel teachings and advantages of the invention. Accordingly, such modifications are intended to be included within the scope of the invention.

What is claimed is:

1. A noise cancellation circuit comprising:
a coil section that includes a wire with a specific shape that is disposed at a position close to a digital signal processing circuit section mounted at a specific position on a substrate, the coil section detecting undesirable radiation generated from the digital signal processing circuit section; and
a cancellation signal generation section that generates a signal that cancels the undesirable radiation detected by the coil section.

2. The noise cancellation circuit as defined in claim 1, the coil section being disposed between the digital signal processing circuit section and the substrate.

3. The noise cancellation circuit as defined in claim 2, the coil section being disposed between a specific circuit section and the substrate, the specific circuit section forming the digital signal processing circuit section.

4. The noise cancellation circuit as defined in claim 2, the coil section being disposed between a memory circuit section and the substrate, the memory circuit section forming the digital signal processing circuit section.

5. The noise cancellation circuit as defined in claim 1, the coil section including a wire disposed along a periphery of the digital signal processing circuit section.

6. An electronic circuit comprising the noise cancellation circuit as defined in claim 1 and the digital signal processing circuit section.

7. The electronic circuit as defined in claim 6, the digital signal processing circuit section being flip-chip mounted over the coil section.

8. The electronic circuit as defined in claim 6, the digital signal processing circuit section being a GPS satellite signal processing circuit section.

9. The electronic circuit as defined in claim 7, the digital signal processing circuit section being a GPS satellite signal processing circuit section.

10. A noise cancellation signal generation method comprising:
disposing a coil section that detects undesirable radiation generated from a digital signal processing circuit section mounted at a specific position on a substrate, the coil section including a wire with a specific shape that is disposed at a position close to the digital signal processing circuit section; and
generating a signal that cancels the undesirable radiation detected by the coil section.

11. The noise cancellation signal generation method as defined in claim 10, the method further including disposing the coil section between the digital signal processing circuit section and the substrate.

12. The noise cancellation signal generation method as defined in claim 10, the method further including disposing the coil section between a specific circuit section and the substrate, the specific circuit section forming the digital signal processing circuit section.

13. The noise cancellation signal generation method as defined in claim 11, the method further including disposing the coil section between a memory circuit section and the substrate, the memory circuit section forming the digital signal processing circuit section.

14. The noise cancellation signal generation method as defined in claim 10, the method further including forming the coil section using a wire disposed along a periphery of the digital signal processing circuit section.
